(19) United States
(12) Patent Application Publication
(10) Pub. No.: US 2025/0385158 A1
(43) Pub. Date: Dec. 18, 2025

(54) THERMAL INTERFACE MATERIAL HEAT TRANSFER ANTENNAS

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 18/816,239

(22) Filed: Aug. 27, 2024

Related U.S. Application Data
(60) Provisional application No. 63/659,028, filed on Jun. 12, 2024.

(51) Int. Cl. H01L 23/433; H01L 23/498; H01L 23/538; H01L 23/64; H01L 25/065

(52) U.S. Cl. CPC H01L 23/433; H01L 23/49816; H01L 23/49827; H01L 23/5383; H01L 23/645; H01L 25/0655

(57) ABSTRACT

A semiconductor device having a front and a back and comprising a package substrate, an epoxy base layer applied to a back side of the package substrate, and a planar inductor in the epoxy base layer is etched to make a trench at the back of the semiconductor device in the epoxy base layer adjacent the planar inductor, and a thermal interface material is put in the trench, whereby a heat transfer antenna is formed. A semiconductor device has a package substrate having a front and a back; an epoxy base layer applied to a back side of the package substrate, a planar inductor at the back of the package substrate in the epoxy base layer, and a heat transfer antenna at the back of the package substrate in the epoxy base layer.

### PRIORITY

This application claims priority to U.S. Provisional Patent Application No. 63/659,028, filed Jun. 12, 2024, the contents of which are hereby incorporated in their entirety.

### TECHNICAL FIELD

The present disclosure relates to heat transfer in semiconductor devices.

### BACKGROUND

Efficient removal of heat is very important and challenging for modern electronic systems. Improved heat removal results in improved performance for the system.

Water-cooled and air-cooled semiconductor device systems have been widely utilized. They are not sufficient to meet the high cooling demands of modern electronic systems and allow them to operate at peak performance.

There is a need for heat transfer in semiconductor devices.

### SUMMARY OF THE INVENTION

Aspects provide a three-dimensional implementation of Thermal Interface Material (TIM) in trenches cut into the back side of semiconductor devices (Heat Transfer Antennas-HTA). A further aspect provides inductors made of thick copper (˜5 um-25 um) patterned in epoxy. TIM filled trenches near these structures may be utilized to more efficiently remove heat in an air, or water-cooled system. An aspect may provide a heat dissipation path closer to the heat generation source in a semiconductor device.

According to one aspect, there is provided a method comprising: providing a semiconductor device having a front and a back and comprising: a package substrate; an epoxy base layer applied to a back side of the package substrate; and a planar inductor in the epoxy base layer; etching a trench at the back of the semiconductor device in the epoxy base layer adjacent the planar inductor; and forming a heat transfer antenna by putting thermal interface material in the trench.

An aspect according to the previous paragraph provides a method, wherein the trench is in the epoxy base layer adjacent the planar inductor.

An aspect according to the previous two paragraphs provides a method, wherein the semiconductor device comprises a die at the back of the semiconductor device and the trench is in the die.

An aspect according to the previous three paragraphs provides a method, wherein the trench extends into the die until just before a doped region of the die.

An aspect according to the previous four paragraphs provides a method, comprising: etching a channel at the back of the semiconductor device in the epoxy base layer; and positioning material to form the planar inductor in the channel.

An aspect according to the previous five paragraphs provides a method, comprising planarizing a back side of the epoxy base layer and material to form the planar inductor.

An aspect according to the previous six paragraphs provides a method, comprising depositing an epoxy cap layer on the back of the semiconductor device, whereby the planar inductor is encapsulated.

An aspect according to the previous seven paragraphs provides a method, wherein the planar inductor comprises copper.

An aspect according to the previous eight paragraphs provides a method, wherein the semiconductor device has a thickness of 500 μm-700 μm, and the trench has a width of 5 μm-15 μm and a depth of 50 μm-100 μm.

An aspect according to the previous nine paragraphs provides a method, comprising putting thermal interface material into the trench with a wiper blade.

An aspect according to the previous ten paragraphs provides a method, comprising planarizing thermal interface material in the trench at the back of the semiconductor device.

According to an aspect, there is provided a device comprising: a package substrate having a front and a back; an epoxy base layer applied to a back side of the package substrate; a planar inductor at the back of the package substrate in the epoxy base layer; and a heat transfer antenna at the back of the package substrate in the epoxy base layer.

An aspect according to the previous paragraph provides a device, wherein the heat transfer antenna is adjacent the planar inductor.

An aspect according to the previous two paragraphs provides a device, comprising a die at the back of the semiconductor device and the heat transfer antenna is in the die.

An aspect according to the previous three paragraphs provides a device, wherein the heat transfer antenna extends into the die until just before a doped region of the die.

An aspect according to the previous four paragraphs provides a device, comprising a redistribution layer applied to a front side of the package substrate.

An aspect according to the previous five paragraphs provides a device, comprising an epoxy cap layer on the back of the semiconductor device encapsulating the planar inductor.

An aspect according to the previous six paragraphs provides a device, wherein the planar inductor comprises copper.

An aspect according to the previous seven paragraphs provides a device, wherein the semiconductor device has a thickness of 500 μm-700 μm, and the heat transfer antenna has a width of 5 μm-15 μm and a depth of 50 μm-100 μm.

An aspect according to the previous eight paragraphs provides a device, wherein the heat transfer antenna provides shallow trench isolation, whereby the heat transfer antenna reduces electric current leakage between adjacent semiconductor device components.

### BRIEF DESCRIPTION OF THE DRAWINGS

The figures illustrate examples of semiconductor devices with a three-dimensional implementation of Thermal Interface Material (TIM) formed in trenches cut into the back side of semiconductor devices (Heat Transfer Antennas-HTA).

FIG. 1 shows a cross-sectional side view of a semiconductor device.

FIG. 2 shows a top view of an inductor positioned in a semiconductor device (not shown).

FIGS. 3A-3F show cross-sectional side views of a semiconductor device at progressive phases of construction.

FIG. 3A shows a cross-sectional side view of a semiconductor device, which in this non-limiting example, is a fan out package.

FIG. 3B shows a cross-sectional side view of the semiconductor device shown in FIG. 3A.

FIG. 3C shows a cross-sectional side view of the semiconductor device shown in FIGS. 3A-3B.

FIG. 3D shows a cross-sectional side view of the semiconductor device shown in FIGS. 3A-3C.

FIG. 3E shows a cross-sectional side view of the semiconductor device shown in FIGS. 3A-3D.

FIGS. 3F and 3G show cross-sectional side views of the semiconductor device 300 shown in FIGS. 3A-3E at various moments in a process of putting thermal interface material (TIM) into the trenches to form heat transfer antennas (HTA).

FIG. 3H shows a cross-sectional side view of the semiconductor device shown in FIGS. 3A-3G.

FIG. 4 shows a cross-sectional side view of the semiconductor device made by the process shown in FIGS. 3A-3H.

FIG. 5 shows a cross-sectional side view of the semiconductor device made by the process shown in FIGS. 3A-3G.

FIG. 6 shows a cross-sectional side view of the semiconductor device made by the process shown in FIGS. 3A-3G.

FIG. 7 is a flow chart of a method to provide a three-dimensional implementation of TIM in trenches cut into the back side of semiconductor devices to make heat transfer antennas.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a three-dimensional implementation of Thermal Interface Material (TIM) into trenches cut into the back side of semiconductor devices (Heat Transfer Antennas-HTA). An aspect provides the formation of inductors made of thick copper (˜5 um-25 um) patterned in epoxy. TIM filled trenches near these structures may be utilized to more efficiently remove heat in an air, or water-cooled system.

Channels cut into the epoxy closer to the source of heat generation and then filled with a high thermal conductivity material may allow for more efficient heat transfer/dissipation.

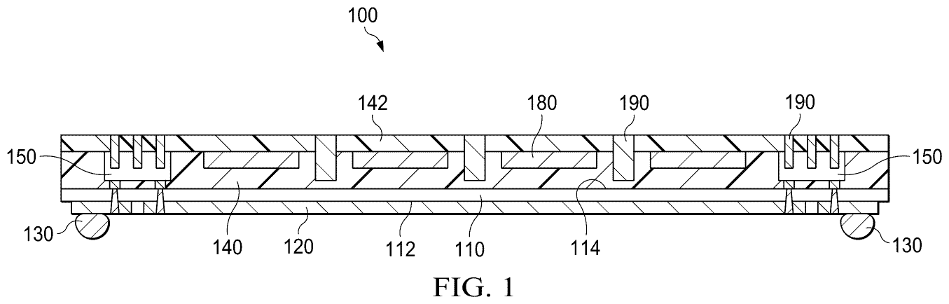

FIG. 1 shows a cross-sectional side view of a semiconductor device. The semiconductor device 100 has a package substrate 110 having a front side 112 and a back side 114. A redistribution layer 120 is applied to the front side 112 of the package substrate 110. Solder bumps 130 are applied to the redistribution layer 120. An epoxy base layer 140 is applied to the back side 114 of the package substrate 110. Two dies 150 are positioned in the epoxy base layer 140. For example, the dies 150 may be integrated passive device (IPD), power switch, controller, or driver dies. Vias 160 extend through the redistribution layer 120. Solder bumps 130 are applied to the redistribution layer 120 to provide contacts for communication with the dies 150 by way of the vias 160. An inductor 180 is also positioned in the epoxy base layer 140. An epoxy cap layer 142 encapsulates the dies 150 and the inductor 180 in epoxy. Heat transfer antennas 190 are positioned in the epoxy of the epoxy base layer 140 and the epoxy cap layer 142.

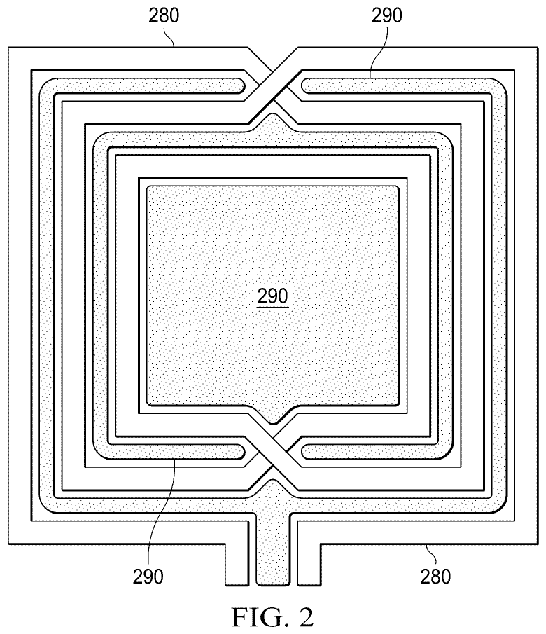

FIG. 2 shows a top view of an inductor 280 positioned in a semiconductor device (not shown). Between the coils of the inductor 280, heat transfer antennas 190 are positioned to conduct heat from the inductor 280.

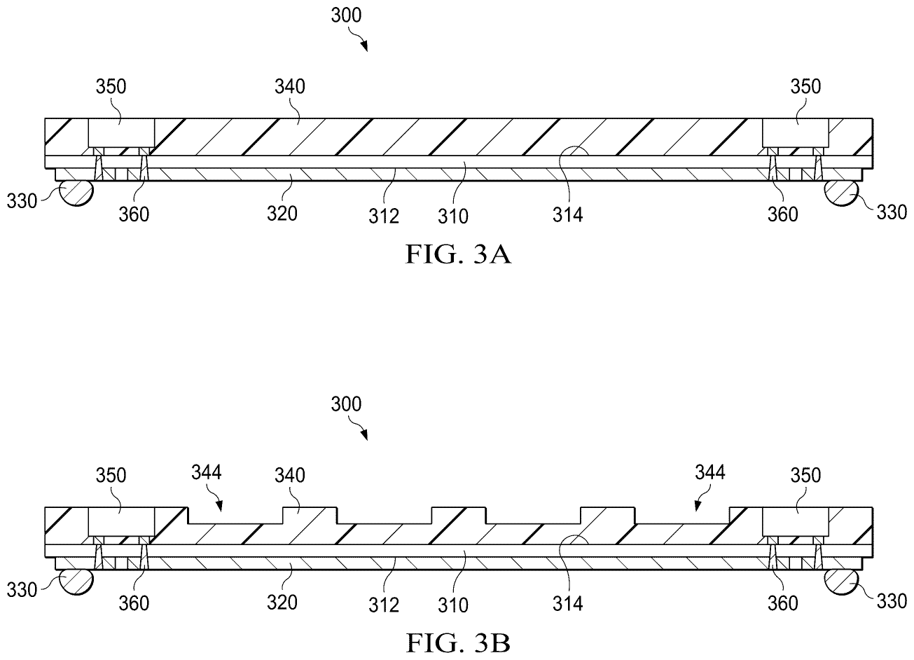

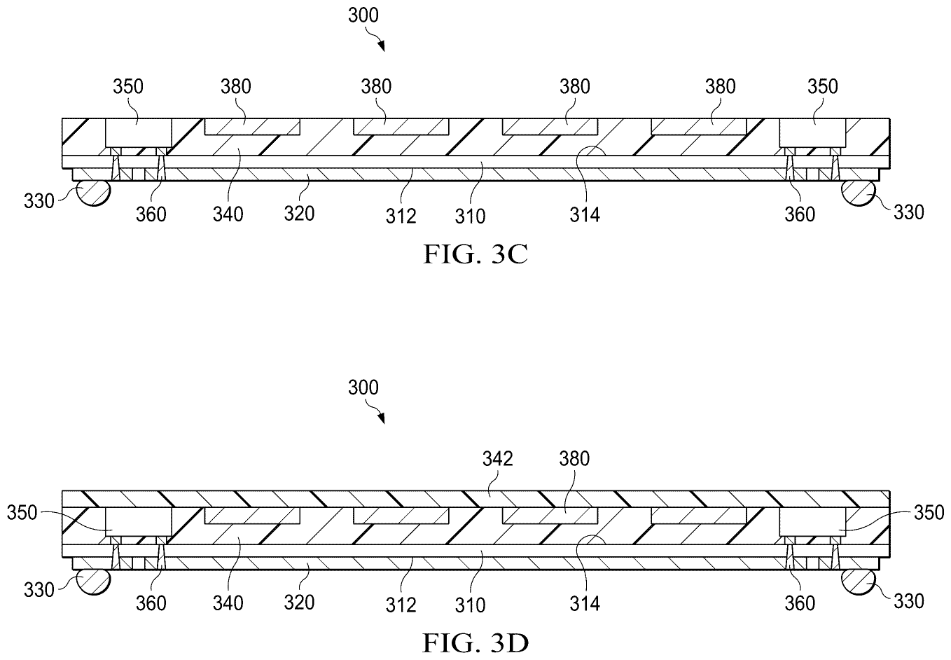

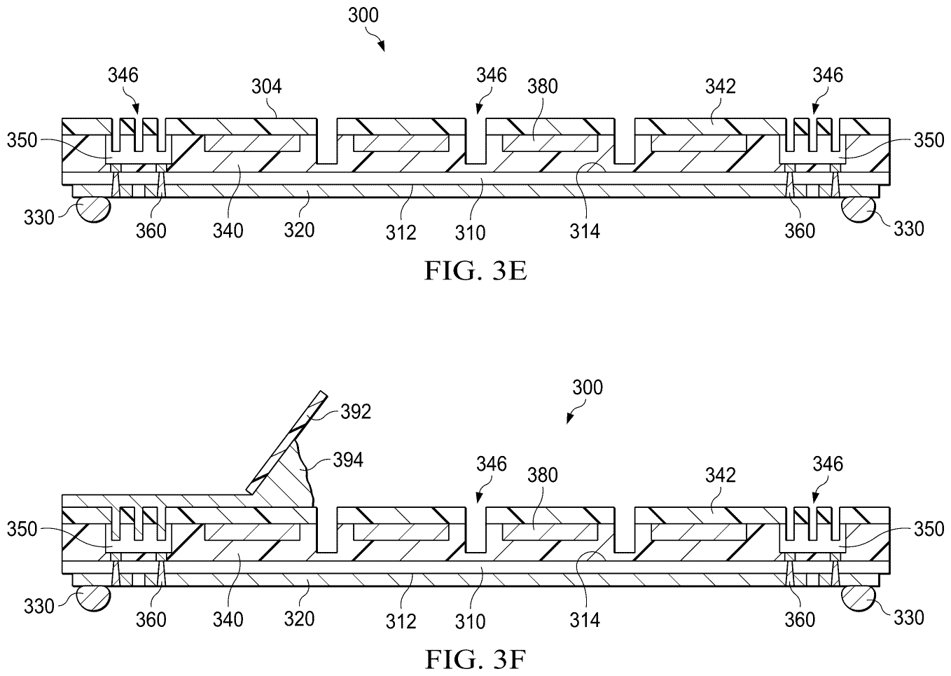

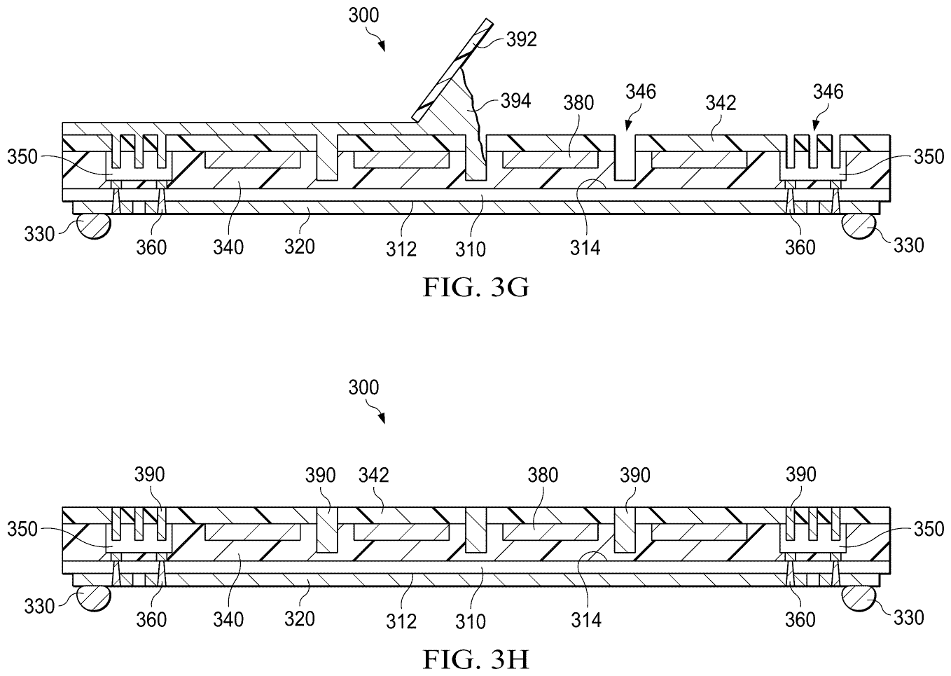

FIGS. 3A-3F show cross-sectional side views of a semiconductor device at progressive phases of construction.

FIG. 3A shows a cross-sectional side view of a semiconductor device, which in this non-limiting example, is a fan out package. The semiconductor device 300 has a package substrate 310 having a front side 312 and a back side 314. A redistribution layer 320 is applied to the front side 312 of the package substrate 310. An epoxy base layer 340 is applied to the back side 314 of the package substrate 310. Two dies 350 are positioned in the epoxy base layer 340. For example, the dies 350 may be integrated passive device (IPD), power switch, controller, or driver dies. Vias 360 extend through the redistribution layer 320. Solder bumps 330 are applied to the redistribution layer 320 to provide contacts for communication with the dies 150 by way of the vias 160.

FIG. 3B shows a cross-sectional side view of the semiconductor device 300 shown in FIG. 3A. The epoxy base layer 340, applied to the back side 314 of the package substrate 310, has channels 344 in a pattern for a planar inductor. The channels 344 may be formed by an etch process.

FIG. 3C shows a cross-sectional side view of the semiconductor device 300 shown in FIGS. 3A-3B. An inductor 380 is positioned in the channels (see FIG. 3B). The inductor may be copper (Cu) and may be deposited in the channels and thereafter the back side surfaces of the semiconductor device may be planarized.

FIG. 3D shows a cross-sectional side view of the semiconductor device 300 shown in FIGS. 3A-3C. An epoxy cap layer 342 is on the back side of the semiconductor device 300. The epoxy cap layer 342 may be a moisture resistant epoxy. Because the epoxy cap layer 342 serves as the moisture barrier for the semiconductor device 300, the moisture resistance qualities of this epoxy may be more effective compared to the moisture resistance qualities of the epoxy of the epoxy base layer 340.

FIG. 3E shows a cross-sectional side view of the semiconductor device 300 shown in FIGS. 3A-3D. The semiconductor device 300 has trenches 346 in the back side 304 of the semiconductor device 300 extending through the epoxy cap layer 342 and into the epoxy base layer 340 or the dies 350. According to one example, the semiconductor device 300 has a thickness of about 500 μm-700 μm, and a trench 346 has a width of about 5 μm-15 μm and a depth of about 50 μm-100 μm. The trenches 346 extending into the epoxy base layer 340 may be wider than the trenches 346 extending into the dies 350. The trenches 346 extending into the dies 350 may extend into the dies 350 until just before they reach the junction P-doped and N-doped regions of the dies 350. The trenches 346 may be formed by a laser etch process. The trenches 346 may provide shallow trench isolation. Shallow trench isolation (STI), also known as box isolation technique, is an integrated circuit feature that may prevent electric current leakage between adjacent semiconductor device components.

FIGS. 3F and 3G show cross-sectional side views of the semiconductor device 300 shown in FIGS. 3A-3E at various moments in a process of putting thermal interface material (TIM) into the trenches 346 to form heat transfer antennas (HTA) 190. A wiper blade 392 is shown putting TIM 394 into trenches 346 in the back side 304 of the semiconductor device 300 by wiping the TIM 394 across the epoxy cap layer 342. As shown in FIG. 3F, the trenches 346 at a die 350 are completely filled with TIM 394. As shown in FIG. 3G, the trenches 346 at a die 350 are completely filled with TIM 394, a first trench 346 extending into the epoxy base layer 340 is completely filled with TIM 394, and a second trench 346 extending into the epoxy base layer 340 is partially filled with TIM 394 as the wiper blade 392 wipes across the epoxy cap layer 342. The wiper blade 392 may be swiped across the epoxy cap layer 342 until all of the trenches 346 are filled with TIM 394.

In alternatives, the TIM 394 may be put in the trenches 346 by printing, flowing, injecting, pushing, or hammering, without limitation. A flowable TIM 394 may be put in the trenches 346 by printing, flowing, or injecting without limitation. Where the TIM 394 is flowable, a mask may facilitate putting the TIM 394 in a trench 346. A solid or semi-solid TIM 394 may be pushed, pressed, injected, inserted, or hammered, without limitation, into the trench 346. Where the TIM 394 is solid or semi-solid, the TIM 394 may be put in a trench 346 without a mask on the semiconductor device 300.

FIG. 3H shows a cross-sectional side view of the semiconductor device 300 shown in FIGS. 3A-3G, wherein all of the trenches 346 are filled with TIM 394 to form heat transfer antennas 390. The back side of the semiconductor device 300 has been planarized to remove excess TIM 394 so that the exterior surfaces of the heat transfer antennas 390 and the epoxy cap layer 342 are in the same plane.

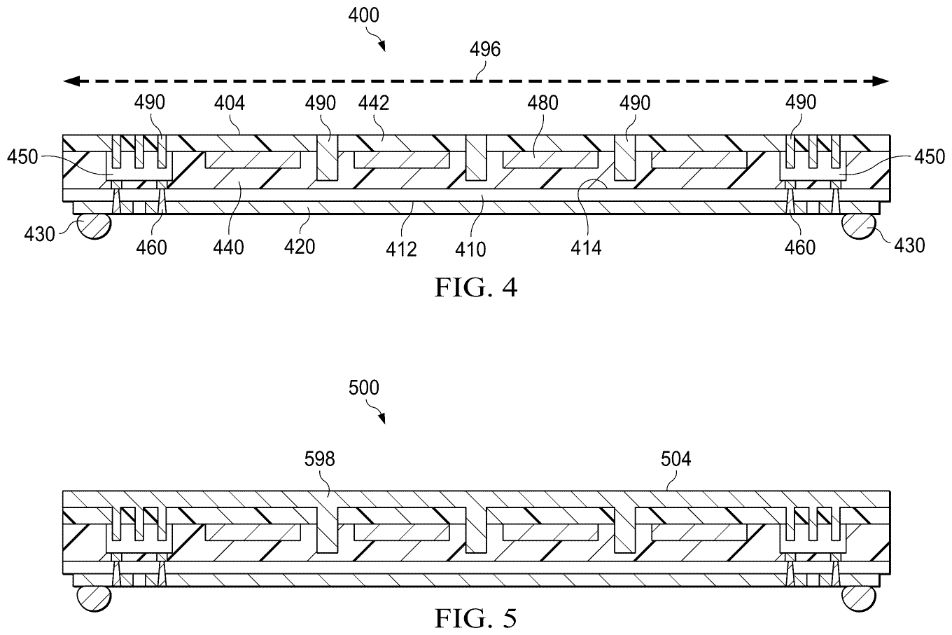

FIG. 4 shows a cross-sectional side view of the semiconductor device 400 made by the process shown in FIGS. 3A-3H. The semiconductor device 400 has a package substrate 410 having a front side 412 and a back side 414. A redistribution layer 420 is applied to the front side 412 of the package substrate 410. Solder bumps 430 are applied to the redistribution layer 420. An epoxy base layer 440 is applied to the back side 414 of the package substrate 410. Two dies 450 are positioned in the epoxy base layer 440. For example, the dies 450 may be integrated passive device (IPD), power switch, controller, or driver dies. Vias 460 extend through the redistribution layer 420. Solder bumps 430 are applied to the redistribution layer 420 to provide contacts for communication with the dies 450 by way of the vias 460. An inductor 480 is also positioned in the epoxy base layer 440. An epoxy cap layer 442 encapsulates the dies 450 and the inductor 480 in epoxy. Heat transfer antennas 490 are positioned in the back side 404 of the semiconductor device 400 extending through the epoxy cap layer 442 and into the epoxy base layer 440 or the dies 450. According to one example, the semiconductor device 400 has a thickness of 500 μm-700 μm, and a heat transfer antenna 490 has a width of about 5 μm-15 μm and a depth of about 50 μm-100 μm. The heat transfer antenna 490 extending into the epoxy base layer 440 may be wider than the heat transfer antenna 490 extending into the dies 450. The heat transfer antenna 490 extending into the dies 450 may extend into the dies 450 until just before they reach the junction P-doped and N-doped regions of the dies 450. The back side 404 of the semiconductor device 400 may be exposed to a heat transfer medium 496 to remove heat from the semiconductor device 400 by the heat transfer antennas 490.

FIG. 5 shows a cross-sectional side view of the semiconductor device 500 made by the process shown in FIGS. 3A-3G. A difference between the semiconductor device 500 and the semiconductor device 400 shown in FIG. 4 is that semiconductor device 500 has a TIM layer 498 on the back side 504.

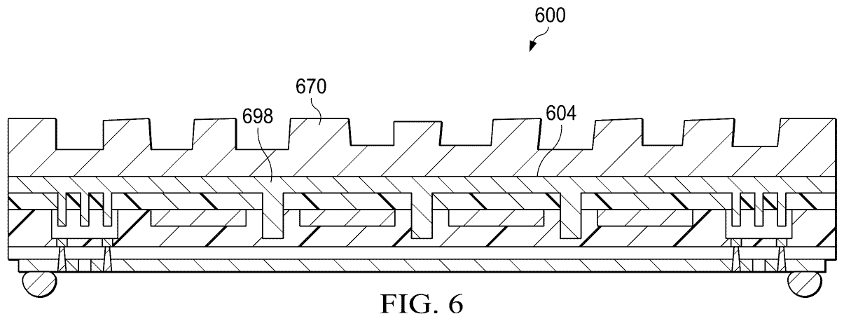

FIG. 6 shows a cross-sectional side view of the semiconductor device 600 made by the process shown in FIGS. 3A-3G. A difference between the semiconductor device 600 and the semiconductor device 500 shown in FIG. 5 is that a heat sink 670 is attached to the back side 604 of the semiconductor device 600.

Aspects may provide efficient removal of heat from the semiconductor devices. Semiconductor devices may have inductors (transformers) in the epoxy both on and off of the circuit board while simultaneously having heat transfer antennas for enhanced cooling.

Thermal interface materials (TIM) include material that thermally couple two components, typically for heat transfer from one component to another component. For example, TIM may include: thermal paste, thermal adhesive, thermal gap filler, thermally conductive pads, thermal tape, polymers, phase-change materials, metals, thermal greases, and thermal gels. Thermal paste may include materials with low mechanical strength but sufficient viscosity to allow it to stay in position during use. Thermal adhesive may contain additives to improve thermal conductivity, including solid fillers (metal oxides, carbon black, carbon nanotubes, without limitation), or liquid metal droplets. Thermal gap filler may be a curing paste or adhesive glue with relatively limited adhesiveness. Thermally conductive pads may be a solid state material, for example, silicone or silicone-like material. Thermal tape may be a solid or semisolid material that adheres to surfaces without curing. Phase-change materials are naturally sticky and change to a half-liquid state to be flowable. Metal materials include relatively soft and compliant indium alloys, as well as sintered silver. Thermal greases may provide good gap filling capability and high thermal conductivity. However, short to long term grease pumping may produce interface voiding and thermal degradation at regions of high strain. Thermal gels may provide good gap filling capability.

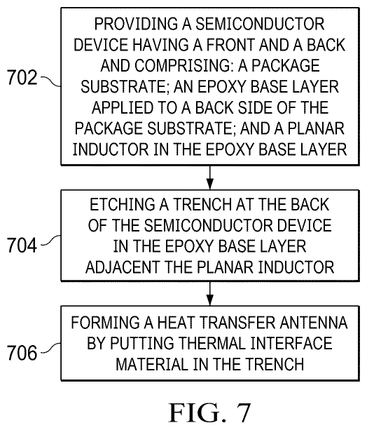

FIG. 7 is a flow chart of a method to provide a three-dimensional implementation of TIM in trenches cut into the back side of semiconductor devices to make heat transfer antennas. A semiconductor device is provided 702 having a front and a back and comprising: a package substrate; an epoxy base layer applied to a back side of the package substrate; and a planar inductor in the epoxy base layer. A trench is etched 704 at the back of the semiconductor device in the epoxy base layer adjacent the planar inductor. A heat transfer antenna is formed 706 by putting thermal interface material in the trench.

Although examples have been described above, other variations and examples may be made from this disclosure without departing from the spirit and scope of these disclosed examples.

1. A method comprising:
providing a semiconductor device having a front and a back and comprising:
a package substrate;
an epoxy base layer applied to a back side of the package substrate; and
a planar inductor in the epoxy base layer;
etching a trench at the back of the semiconductor device in the epoxy base layer adjacent the planar inductor; and
forming a heat transfer antenna by putting thermal interface material in the trench.

2. The method as in claim 1, wherein the trench is in the epoxy base layer adjacent the planar inductor.

3. The method as in claim 1, wherein the semiconductor device comprises a die at the back of the semiconductor device and the trench is in the die.

4. The method as in claim 3, wherein the trench extends into the die until just before a doped region of the die.

5. The method as in claim 1, comprising:
etching a channel at the back of the semiconductor device in the epoxy base layer; and
positioning material to form the planar inductor in the channel.

6. The method as in claim 5, comprising planarizing a back side of the epoxy base layer and material to form the planar inductor.

7. The method as in claim 5, comprising depositing an epoxy cap layer on the back of the semiconductor device, whereby the planar inductor is encapsulated.

8. The method as in claim 1, wherein the planar inductor comprises copper.

9. The method as in claim 1, wherein the semiconductor device has a thickness of 500 μm-700 μm, and the trench has a width of 5 μm-15 μm and a depth of 50 μm-100 μm.

10. The method as in claim 1, comprising putting thermal interface material into the trench with a wiper blade.

11. The method as in claim 1, comprising planarizing thermal interface material in the trench at the back of the semiconductor device.

12. A device comprising:
a package substrate having a front and a back;
an epoxy base layer applied to a back side of the package substrate;
a planar inductor at the back of the package substrate in the epoxy base layer; and
a heat transfer antenna at the back of the package substrate in the epoxy base layer.

13. The device as in claim 12, wherein the heat transfer antenna is adjacent the planar inductor.

14. The device as in claim 12, comprising a die at the back of the package substrate and the heat transfer antenna is in the die.

15. The device as in claim 14, wherein the heat transfer antenna extends into the die until just before a doped region of the die.

16. The device as in claim 12, comprising a redistribution layer applied to a front side of the package substrate.

17. The device as in claim 12, comprising an epoxy cap layer on the back of the package substrate encapsulating the planar inductor.

18. The device as in claim 12, wherein the planar inductor comprises copper.

19. The device as in claim 12, wherein the device has a thickness of 500 μm-700 μm, and the heat transfer antenna has a width of 5 μm-15 μm and a depth of 50 μm-100 μm.

20. The device as in claim 12, wherein the heat transfer antenna provides shallow trench isolation, whereby the heat transfer antenna reduces electric current leakage between adjacent semiconductor device components.
